(19) United States
(12) Patent Application Publication
(10) Pub. No.: US 2026/0026350 A1
(43) Pub. Date: Jan. 22, 2026

(54) SEGMENTED SEAL RINGS AND METHODS OF MAKING THEREOF

(71) Applicant: GlobalFoundries Singapore Pte. Ltd., Singapore (SG)

(72) Inventors: WANBING YI, Singapore (SG); DAU FATT LIM, Singapore (SG); KAI KANG, Singapore (SG); KWANG SING YEW, Singapore (SG)

(21) Appl. No.: 18/777,540

(22) Filed: Jul. 19, 2024

(51) Int. Cl. H01L 23/58; H01L 23/00

(52) U.S. Cl. CPC H01L 23/585; H01L 23/562

(57) ABSTRACT

Semiconductor devices including seal rings and method of making the same is provided. A semiconductor device comprises an interconnect layer over a substrate. The interconnect layer comprises a barrier layer over a dielectric layer. A seal ring is in the interconnect layer and the seal ring extends through the interconnect layer to abut the substrate. An insulator layer is around the seal ring and the insulator layer spaces the seal ring from the barrier layer. A protective structure is laterally adjacent to the seal ring and the protective structure extends through the interconnect structure to abut the substrate. The seal ring may be segmented and comprises a first segment in a first trench in an interconnect stack, and a second segment in a second trench in the interconnect stack.

### FIELD OF THE INVENTION

The present invention relates generally to semiconductor structures, and more particularly to segmented seal rings and methods of making segmented seal rings.

### BACKGROUND

Semiconductor wafers typically undergo back-end processes such as dicing processes in which individual semiconductor chips are diced from the semiconductor wafers. During dicing processes, the semiconductor chips could be exposed to moisture that could damage the circuits and other components if the moisture enters the chips. The mechanical dicing process could also cause other types of damages to the semiconductor chips, such as cracks and peeling of layers.

To alleviate such damages caused by dicing processes, the industry has utilized various measures such as guard rings and seal structures to arrest cracks and prevent crack propagation, as well as provide barriers against the ingress of moisture into the semiconductor chips. However, many measures are lacking in either process compatibility or effectiveness. Improved structures and methods for making such structures are desired.

### SUMMARY

According to an embodiment of the invention, a semiconductor device comprising an interconnect layer over a substrate is provided. The interconnect layer comprises a dielectric layer over the substrate and a barrier layer over the dielectric layer. A seal ring is in the interconnect layer and the seal ring extends through the interconnect layer to abut the substrate. An insulator layer is around the seal ring. A protective structure is laterally adjacent to the seal ring and the protective structure extends through the interconnect layer to abut the substrate.

According to another embodiment of the invention, a semiconductor device comprising an interconnect stack over a substrate is provided, wherein the interconnect stack comprises a first dielectric layer, a barrier layer over the first dielectric layer and a second dielectric layer over the barrier layer. A first trench is in the interconnect stack, wherein the first trench extends through the barrier layer to abut the substrate and the first trench has a first sidewall. An insulator layer is on the first sidewall of the first trench. A first seal ring segment is in the first trench, wherein the first seal ring segment is spaced from the barrier layer by the insulator layer. A protective structure is in the interconnect stack, wherein the protective structure is laterally adjacent to the first seal ring segment and extends through the barrier layer to abut the substrate.

According to yet another embodiment of the invention, it is provided a method of fabricating a semiconductor device comprises the forming of an interconnect stack over a substrate, wherein the interconnect stack comprises a first dielectric layer, a barrier layer over the first dielectric layer and a second dielectric layer over the barrier layer. The method also comprises forming a first trench in the interconnect stack, wherein the first trench extends through the barrier layer to abut the substrate and the first trench has a first sidewall, and forming an insulator layer on the first sidewall of the first trench. The method further comprises forming a first seal ring segment in the first trench, wherein the first seal ring segment is spaced from the barrier layer by the insulator layer, and forming a protective structure in the interconnect stack, wherein the protective structure is laterally adjacent to the seal ring and extends through the barrier layer to abut the substrate.

### BRIEF DESCRIPTION OF THE DRAWINGS

The accompanying drawings illustrate examples of various non-limiting embodiments of the invention and constitute a part of the specification. The drawings, along with the above general description of the invention, and the following detailed description of the various embodiments, serve to explain the examples of the non-limiting embodiments of the invention. In the drawings, like reference numerals generally refer to like features in the various views.

FIG. 1A shows a simplified top-down view of a semiconductor chip according to an exemplary embodiment of the disclosure.

FIG. 1B shows a simplified cross-sectional view of a section of semiconductor chip across line A-A′ in FIG. 1A, according to another exemplary embodiment of the disclosure.

FIG. 2 shows a simplified cross-sectional view of a section of semiconductor chip, according to an exemplary embodiment of the disclosure.

FIG. 3 shows a simplified cross-sectional view of a section of semiconductor chip, according to an exemplary embodiment of the disclosure.

FIGS. 4A-4D show simplified cross-sectional views representing exemplary process steps for fabricating the section of the semiconductor chip shown in FIG. 1A, according to exemplary embodiments of the invention.

FIGS. 5A-5B show simplified cross-sectional views representing exemplary process steps for fabricating the section of the semiconductor chip shown in FIG. 2, according to exemplary embodiments of the invention.

FIGS. 6A-6C show simplified cross-sectional views representing exemplary process steps for fabricating the section of the semiconductor chip shown in FIG. 3, according to exemplary embodiments of the invention.

For simplicity and clarity of illustration, the drawings illustrate the general manner of construction, and certain descriptions and details of well-known features and techniques may be omitted to avoid unnecessarily obscuring the discussion of the described embodiments of the device. Additionally, elements in the drawings are not necessarily drawn to scale and the dimensions of some of the elements in the drawings may be exaggerated relative to other elements to help improve understanding of the embodiments of the device.

### DETAILED DESCRIPTION

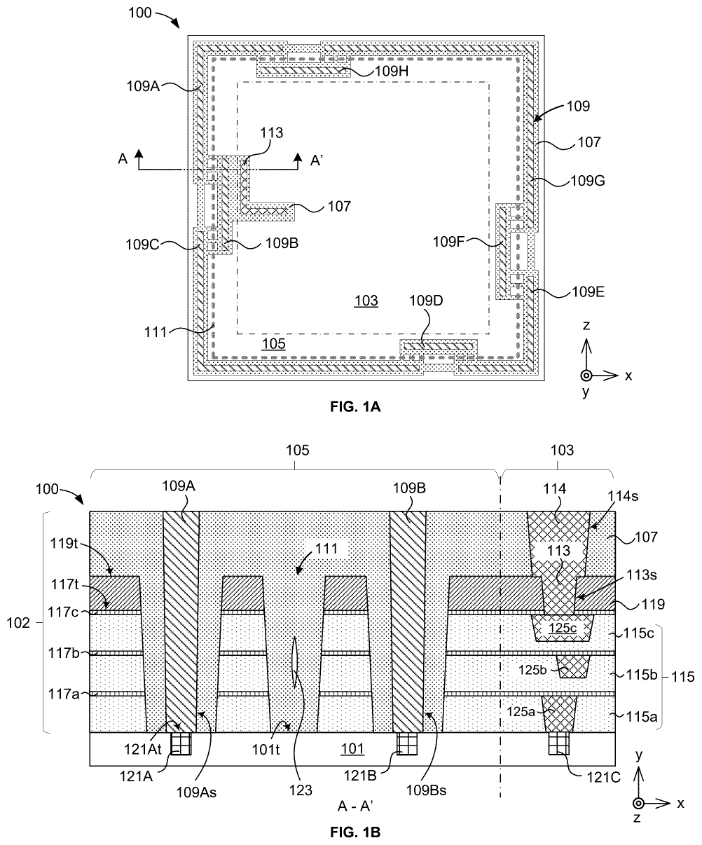

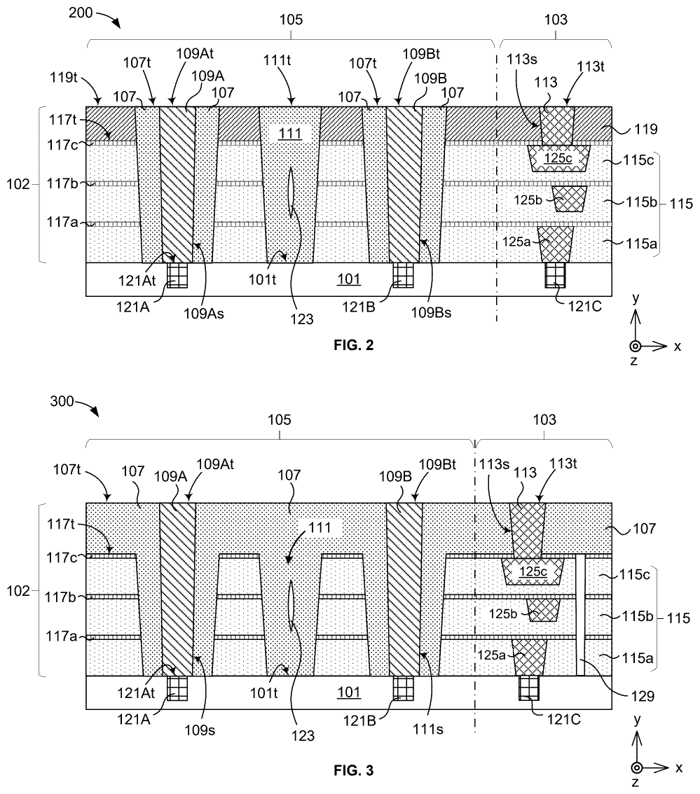

According to an exemplary embodiment of the disclosure, FIG. 1A shows a semiconductor chip 100 which includes an active region 103, a chip edge region 105 annularly surrounding the active region 103. In an un-diced semiconductor wafer, a scribe line region (not shown) annularly surrounds the chip edge region 105 and the active region 103. During the dicing process, the semiconductor wafer is typically sawn along the scribe line regions to obtain diced semiconductor chips, similar to semiconductor chip 100. The active region 103 is designated for active semiconductor devices, including transistors, resistors, memory cells and the like. The chip edge region 105 may include protective structures such as seal rings and moisture barriers. For example, chip edge region 105 may include a seal ring 109 annularly surrounding the active region 103. The seal ring 109 may be surrounded by an insulator layer 107. In some embodiments, the seal ring 109 may be discontinuous and comprise a number of discrete segments which may not be connected to each other, for example, segments 109A-109H as shown in FIG. 1A. Some of the seal ring segments may be laterally overlapping in an axis that is parallel to the chip surface, for example, segment 109A and segment 109B of the seal ring laterally overlap along z-axis as shown in FIG. 1A, such that line A-A′ along x-axis cuts through both segment 109A and segment 109B. Seal ring segments 109A and 109B may also be surrounded by insulator layer 107. In other embodiments (not shown), the seal ring 109 may be continuous and unsegmented. Seal ring 109 may be formed in the back-end-of-line (BEOL) interconnect layer of a semiconductor chip, over the contact layer in substrate 101 and may be connected to one or more contacts in in the contact layer, for enhanced mechanical integrity. Chip edge region 105 may further include a protective structure 111 laterally adjacent to the seal ring 109 and the active region 103. In some embodiments, protective structure 111 may be between the seal ring 109 and the active region 103. In other embodiments, some portions of the protective structure 111 may be between segments of the seal ring 109, for example between segments 109A and 109B as shown in FIG. 1A and FIG. 1B. Protective structure 111 may be continuous, for example, without any breaks in the structure, and annularly surround the active region 103. Protective structure 111 may act as a moisture barrier against moisture ingress into the active region 103. Protective structure 111 may comprise a dielectric material having a dielectric constant κ1. In some embodiments, dielectric constant κ1 is higher than the dielectric constant of silicon dioxide.

Now referring to FIG. 1B, which shows a simplified cross-sectional view of a section of semiconductor chip 100 across line A-A′ in FIG. 1A, the semiconductor chip 100 may include an interconnect layer 102 over a substrate 101. The substrate 101 may include an active layer comprising a semiconductor material. A contact layer comprising contacts, for example contacts 121A, 121B and 121C, may also be present in the substrate 101. Contacts in the contact layer may connect the front-end-of-line semiconductor devices such as transistors to the first layer of the metal interconnects in the interconnect layer 102. Contacts may include conductive materials, such as tungsten. The substrate 101 may include but is not limited to silicon, germanium, silicon germanium (SiGe), silicon carbide, gallium arsenide, or any other suitable integrated circuit (IC) semiconductor substrates. In some embodiments, substrate 101 may be a silicon-on-insulator (SOI) substrate. The interconnect layer 102 may include an insulator layer 107 over a dielectric layer 115. The dielectric layer 115 may comprise multiple layers of dielectric layers 115a, 115b and 115c, as an example. In some embodiments, the dielectric layer 115 may be an interlayer dielectric material having a dielectric constant κ2, where κ2 may be a low dielectric constant (low-K). For example, κ2 may be lower than the dielectric constant of silicon dioxide. As another example, the dielectric constant κ1 of the insulator layer may be higher than the dielectric constant κ2 of the dielectric layer 115. The interconnect layer 102 may further include barrier layers over the dielectric layers. In some embodiments, the barrier layer may directly contact a top surface of the dielectric layer. For example, barrier layer 117c is over and directly contacts the top surface of the dielectric layer 115c. The barrier layers may also be between the dielectric layers, for example, barrier layer 117a may be between dielectric layers 115a and 115b, and barrier layer 117b may be between dielectric layers 115b and 115c. Barrier layers 117a, 117b and 117c may be etch stop layers in some embodiments. Barrier layers may provide higher etch selectivity compared to the dielectric layers, for example, with the dielectric layers being etched preferentially compared to the barrier layers. In some embodiments, the barrier layers may comprise a nitride material, for example, silicon nitride. In other embodiments, the barrier layers may comprise carbon, for example, silicon carbide, nitrogen doped silicon carbide or nitrogen doped hydrogenated silicon carbide as non-limiting examples. In some embodiments, an oxide layer 119 may be between the dielectric layer 115 and the insulator layer 107. The oxide layer 119 may be over the dielectric layer 115. In some embodiments, the oxide layer 119 may be over and directly contact the top surface of a barrier layer, for example, oxide layer 119 may abut the topmost surface 117t of the barrier layer 117c. The oxide layer 119 may be under the insulator layer 107, and oxide layer 119 may abut the insulator layer 107, for example, oxide layer 119 may have a top surface 119t in direct contact with the insulator layer 107. The top surface 119t may be a topmost surface of the oxide layer 119. In some embodiments, the oxide layer 119 may comprise an oxide, for example silicon dioxide. In other embodiments, the oxide layer 119 may comprise a fluorine-doped silica glass.

Still referring to FIG. 1B, the chip edge region 105 is laterally adjacent and connected to the active region 103. The chip edge region 105 may include segments of the seal ring in the insulator layer 107, for example, segment 109A and segment 109B are surrounded by the insulator layer 107. In some embodiments, the insulator layer 107 may abut the seal ring segments 109A and 109B. First referring to segment 109A, the segment 109A is spaced from dielectric layer 115 by the insulator layer 107. When a feature is “spaced from” another feature by a layer, it may mean that the layer is between and abutting the two features without any other intervening layers between the two features. For example, insulator layer 107 may have a surface abutting segment 109A and an opposing surface abutting dielectric layer 115, without other intervening layers between segment 109A and dielectric layer 115. Segment 109A may also be spaced from a barrier layer, for example, barrier layers 117a, 117b and 117c, by the insulator layer 107. Insulator layer 107 may extend vertically (for example, generally along y-axis) through the interconnect layer to a top surface 101t of the substrate 101. The side surface 109As of the segment 109A may abut the insulator layer 107. Segment 109A extends vertically through the interconnect layer 102 to connect to corresponding contact 121A. Contact 121A may be vertically positioned below segment 109A. For example, segment 109A may abut the top surface 121At of contact 121A. Similarly, segment 109B is spaced from dielectric layer 115 by the insulator layer 107. Segment 109B may also be spaced from a barrier layer, for example, barrier layers 117a, 117b and 117c, by the insulator layer 107. The side surface 109Bs of the segment 109B may abut the insulator layer 107. Segment 109B extends vertically through the interconnect layer 102 to connect to corresponding contact 121B, which may be vertically positioned below segment 109B. For example, segment 109B may abut the top surface of contact 121B. The barrier layers may be discontinuous in regions where the insulator layer 107 extends through the interconnect layer 102. For example, within the chip edge region 105, there may be breaks in a barrier layer, for example barrier layer 117a, where portions of the insulator layer 107 extend through the interconnect layer 102 to abut the top surface 101t of the substrate 101, for example, the portion of insulator layer 107 surrounding seal ring segment 109A. The chip edge region 105 may further include protective structure 111 which is laterally adjacent to segments of the seal ring. For example, protective structure 111 may be laterally displaced from segment 109A in the x-axis direction, such that portions of insulator layer 107 and portions of dielectric layer 115 may be between segment 109A and protective structure 111. In some embodiments, protective structure 111 may include an air gap 123. In other embodiments, the air gap 123 may be absent from protective structure 111. The air gap 123 may be completely enclosed within insulator layer 107 and may be vertically displaced from the top surface of substrate 101. Protective structure 111 may be part of insulator layer 107 and extends vertically through the interconnect layer 102 to abut the top surface 101t of the substrate 101. The barrier layers, for example 117a, 117b and 117c, may be discontinuous in regions where the protective structure 111 extends through the interconnect layer 102. For example, within the chip edge region 105, there may be breaks in a barrier layer, for example barrier layer 117a, where the protective structure 111 extends through the interconnect layer 102 to abut the top surface 101t of the substrate 101. In some embodiments, the protective structure 111 may be between a segment of the seal ring 109 and the active region 103, for example, the protective structure 111 may be between segment 109A and active region 103, forming a vertically extending wall around the active region 103. In other embodiments, some portions of the protective structure 111 may be between segments of the seal ring 109, for example, between segment 109A and segment 109B of the seal ring. Active region 103 may include interconnect structures in the interconnect layer 102, for example via 113 and conductive lines 114, 125a, 125b and 125c. In some embodiments, via 113 may be in the oxide layer 119 and conductive line 114 may be in the insulator layer 107. For example, the side surface 113s of the via 113 may abut the oxide layer 119 and the side surface 114s of the conductive line 114 may abut the insulator layer 107. In some embodiments, the side surface 113s may also abut a barrier layer, for example, barrier layer 117c. In some embodiments, the width of via 113 may be smaller than the width of conductive line 114. The conductive line 114 may abut a portion of the top surface of the oxide layer 119, such that the side surface 114s of conductive line 114 is connected to a portion of the top surface of the oxide layer 119, which is in turn connected to the side surface 113s of the via 113. The side surface 114s may form a stepped profile with the side surface 113s. Via 113 may vertically extend through oxide layer 119 to abut a conductive line in the dielectric layer 115, such as conductive line 125c as an example. Conductive lines 125a, 125b and 125c may be in the dielectric layer 115. The seal ring 109 and the interconnect structures may be formed from metallic materials, such as copper. In some embodiments, the material for seal ring 109 and the material for the interconnect structures may be the same.

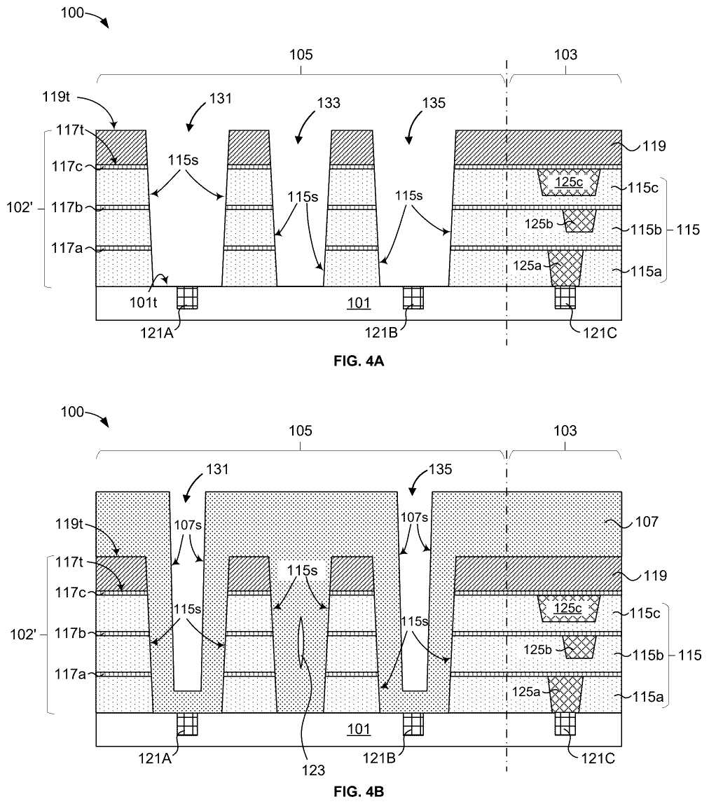

FIG. 2 shows a simplified cross-sectional view of a section of semiconductor chip 200, according to another exemplary embodiment of the disclosure. Semiconductor chip 200 may include features similar to that of semiconductor chip 100 shown in FIG. 1B and like numerals in FIG. 1B may denote like features in FIG. 2. For semiconductor chip 200, the via 113 may be formed in oxide layer 119. For example, a substantial upper portion of the side surface 113s of the via 113 may abut oxide layer 119. A lower portion of the side surface 113s may abut a barrier layer, for example, barrier layer 117c. Via 113 may also have a top surface 113t that is substantially coplanar with the top surface 119t of the oxide layer 119. Segments 109A and 109B of the seal ring 109 may each have a top surface 109At and 109Bt, respectively. In some embodiments, the top surface 113t of the via 113 may be substantially coplanar with the top surface of a seal ring segment, for example, top surface 109At of seal ring segment 109A, and/or the top surface 109Bt of seal ring segment 109B. The protective structure 111 may be spaced from the insulator layer 107 by the dielectric layer 115. The protective structure 111 may have a top surface 111t, and the insulator layer 107 may have a top surface 107t. In some embodiments, the top surface 111t of the protective structure 111 may be substantially coplanar with the top surface 107t of the insulator layer 107. In some embodiments, the top surface 107t of the insulator layer 107 may be substantially coplanar with the top surface 119t of the oxide layer 119.

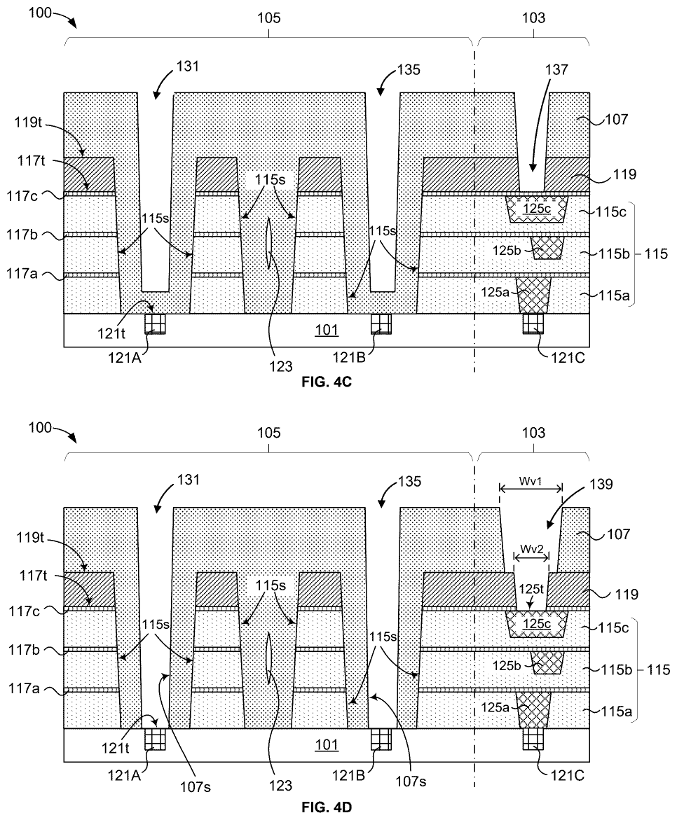

FIG. 3 shows a simplified cross-sectional view of a section of semiconductor chip 300, according to yet another exemplary embodiment of the disclosure. Semiconductor chip 300 may include features similar to that of semiconductor chip 100 shown in FIG. 1B and semiconductor chip 100 shown in FIG. 2. Like numerals in FIG. 1B and FIG. 2 may denote like features in FIG. 3. Semiconductor chip 300 may include an air gap 129 in the dielectric layer 115. The air gap 129 may vertically extend in the y-axis direction through the dielectric layer 115 and may have a narrow width and a high aspect ratio such that air gap 129 remains substantially unfilled after the deposition of insulator layer 107. The oxide layer 119 may be absent, such that the insulator layer 107 abuts a top surface of barrier layer 117 and via 113 may be formed in insulator layer 107. For example, a substantial upper portion of the side surface 113s of the via 113 may abut insulator layer 107. A lower portion of the side surface 113s may abut a barrier layer, for example, barrier layer 117c. In some embodiments, the top surface 113t of the via 113 may be substantially coplanar with the top surface of a seal ring segment, for example, top surface 109At of seal ring segment 109A, and/or the top surface 109Bt of seal ring segment 109B. In some embodiments, the top surface 107t of the insulator layer 107 may be substantially coplanar with the top surface of a seal ring segment, for example, top surface 109At of seal ring segment 109A, and/or the top surface 109Bt of seal ring segment 109B. Protective structure 111 may be connected with insulator layer 107. For example, protective structure may be integral with and may be part of insulator layer 107.

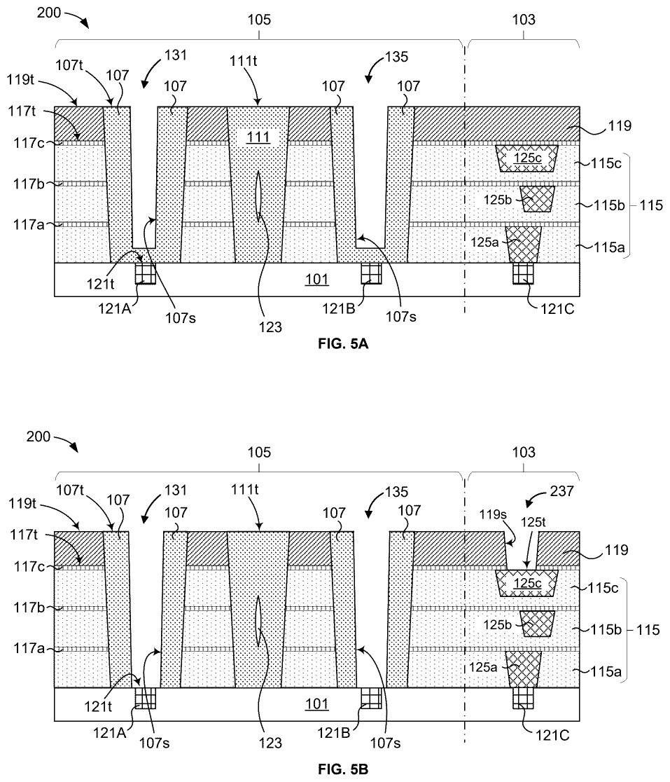

FIGS. 4A-4D illustrate an exemplary process flow for fabricating the section of semiconductor chip 100 shown in FIG. 1A, according to exemplary embodiments of the invention. First referring to FIG. 4A, a substrate 101 including a contact layer comprising, for example, contacts 121A, 121B and 121C, is provided. An interconnect stack 102′ may be formed over the substrate 101 and on the contact layer. The interconnect stack 102′ may include dielectric layer 115 and barrier layers 117a, 117b and 117c. In some embodiments, the interconnect stack 102′ may also include an oxide layer 119. Dielectric layer 115 may be formed in multiple layers of dielectric layers alternated with barrier layers, for example, dielectric layers 115a, 115b and 115c alternated with barrier layers 117a, 117b and 117c, wherein the bottommost dielectric layer abuts the substrate surface 101t and the topmost dielectric layer 115c is covered by and abuts a barrier layer 117c. Dielectric layer 115 may be formed by suitable deposition techniques, such as plasma-enhanced chemical vapor deposition, or spin-on technology, and may be an interlayer dielectric material having a low dielectric constant value (low-K), including, for example, porous silicon dioxide, fluorinated silicon glass or carbon-doped silicon glass, or any other suitable interlayer dielectric material. The barrier layers 117a, 117b and 117c may be formed by a suitable deposition method over a dielectric layer, for example, one or more of the dielectric layers 115a, 115b and 115c. An oxide layer 119 may be formed over the topmost dielectric layer. In some embodiments, the oxide layer 119 may be formed over and abuts the barrier layer 117c.

Subsequently, a number of trenches may be formed in the interconnect stack 102′, exposing the side surfaces 115s of the dielectric material layers and the top surface 101t of the substrate 101. The trenches correspond to breaks in one or more of the barrier layers between the dielectric material layers. The trenches are formed in the chip edge region 105 using a suitable material removal process including the use of a patterned mask (not shown). As an example, a layer of photoresist may be deposited over the oxide layer 119 and patterned to form a suitable patterned mask. An anisotropic wet etch or dry etch process may be used to remove portions of the interconnect stack 102′ which are uncovered by the patterned mask, forming the trenches 131, 133 and 135.

Next referring to FIG. 4B, insulator layer 107 may be formed over the interconnect stack 102′ by a suitable method, such as deposition. For example, the insulator layer 107 may be formed over the top surface 119t of the oxide layer 119. The insulator layer 107 may also be deposited within the trenches 131, 133 and 135, over the exposed side surfaces 115s of the dielectric material layers and over the top surface 101t of the substrate 101. In some of the trenches, the insulator layer 107 may fill up the trench to a level above the top surface 119t of the oxide layer 119, and include an air gap enclosed within the portion of insulator layer 107 in the trench. In some embodiments, the formation of the air gap is due to the pinch-off process during the deposition of insulator layer 107, as a result of the top opening of the trench closing up before the trench is fully filled. For example, trench 133 has an air gap 123 enclosed within the portion of insulator layer 107 in the trench 133, between the oxide layer 119 and the substrate 101. In other trenches, for example, trenches 131 and 135, the insulator layer 107 may conformally line the side walls of the trenches, leaving a gap between the opposing outer side walls 107s of the insulator layer 107. The term “conformal” may refer to when a material layer conforms to or follows the contours of the surface that the material layer is in direct contact with, while maintaining a relatively uniform thickness over the surface. The insulator layer 107 may also line the bottom surfaces of the trenches 131 and 135, for example, bottom portions of the insulator layer 107 may cover the top surface 121t of some contacts in the chip edge region 105, for example contacts 121A and 121B.

Next referring to FIGS. 4C and 4D, vias and lines may be formed in the active region 103 by a suitable process, for example, a dual damascene process. A first material removal process may be performed in the active region, forming a first opening 137 for a via through the insulator layer 107 and the underlying oxide layer 119, exposing the topmost barrier layer, for example, barrier layer 117c, over the dielectric layer 115. A second material removal process may subsequently be performed to form a second opening 139 for conductive lines in the insulator layer 107 above the oxide layer 119. The second material removal process may expose a portion of the top surface of the oxide layer 119 at the bottom of the second opening. The second opening may have a width Wv1 measured across the top of the opening in the insulating layer 107. The second material removal process may also remove the barrier layer 117C at the bottom of the first opening 137 and may expose the top surface 125t of the conductive line 125. The opening in the oxide layer 119 may have a width Wv2 measured across the top of the opening in the oxide layer 119, and width Wv2 may be smaller than width Wv1 in some embodiments.

The second material removal process may simultaneously remove the bottom portions of the insulator layer 107 in trenches 131 and 135, exposing the top surfaces 121t of contacts 121A and 121B in the chip edge region 105. In some embodiments, the second material removal process may be an anisotropic material removal process which preferentially removes material in the downward vertical direction compared to the lateral horizontal direction.

Subsequently, trenches 131 and 135 may be filled with a suitable conductive material to form the seal ring segments 109A and 109B shown in FIG. 1B. In some embodiments, the first and second openings may also be filled with the same conductive material in the same process step to form the via 113 and conductive line 114. Suitable conductive materials may include copper and copper alloys, and may be deposited by electroplating. Barrier layers and seed layers may first be deposited within the trenches and openings to prevent diffusion of the conductive material into the dielectric layer 115, and may be deposited by processes such as electroless, physical vapor, and chemical vapor deposition.

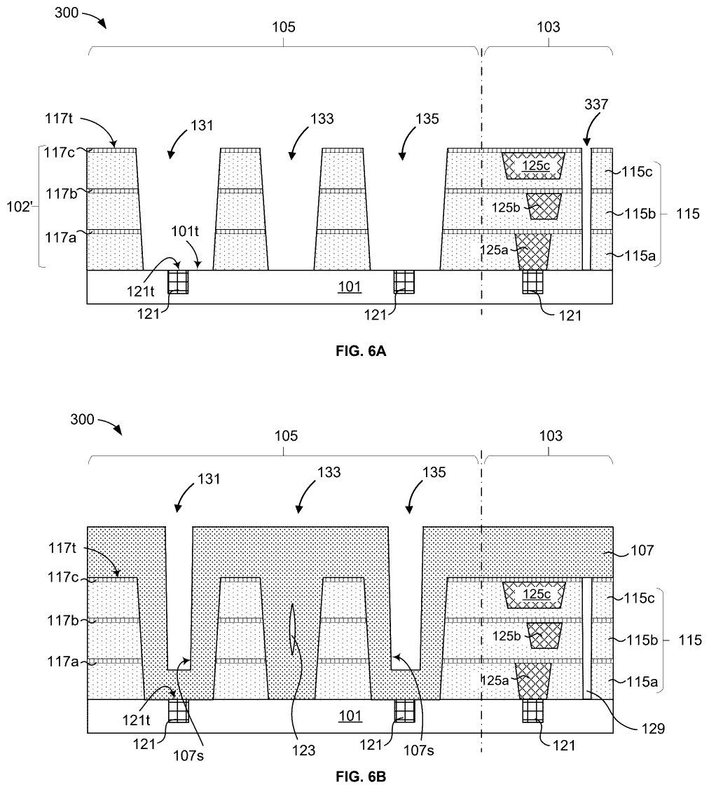

FIGS. 5A-5B illustrate an alternative process flow for fabricating the section of semiconductor chip 200 shown in FIG. 2, according to exemplary embodiments of the invention. FIG. 5A may be subsequent to FIGS. 4A-4B, after a material removal process has been performed to remove a top portion of the insulator layer 107 to expose the top surface 119t of the oxide layer 119. An example of a suitable material removal process may be a chemical mechanical polishing (CMP) process. In some embodiments, the top surface 119t of the oxide layer 119 may be substantially coplanar to the top surface 107t of the insulator layer 107 around the seal ring segments 109A and 109B, and may also be substantially coplanar to the top surface 111t of the protective structure 111.

Now referring to FIG. 5B, a material removal process may be performed in both the active region 103 and the chip edge region 105, forming a through-opening 237 having a side surface 119s in the oxide layer 119, exposing a top surface 125t of the conductive line 125 at the bottom of the opening 237. In some embodiments, the opening 237 may extend through the topmost barrier layer, for example, barrier layer 117c, over the dielectric layer 115. The material removal process may simultaneously remove the bottom portions of the insulator layer 107 in trenches 131 and 135, exposing the top surfaces 121t of contacts 121A and 121B in the chip edge region 105. In some embodiments, the material removal process may be an anisotropic material removal process. Subsequently, trenches 131 and 135 may be filled with a suitable conductive material to form the seal ring segments 109A and 109B shown in FIG. 2. In some embodiments, the opening 237 may also be filled with the same conductive material in the same process step to form the via 113. Suitable conductive materials may include copper and copper alloys, and may be deposited by electroplating.

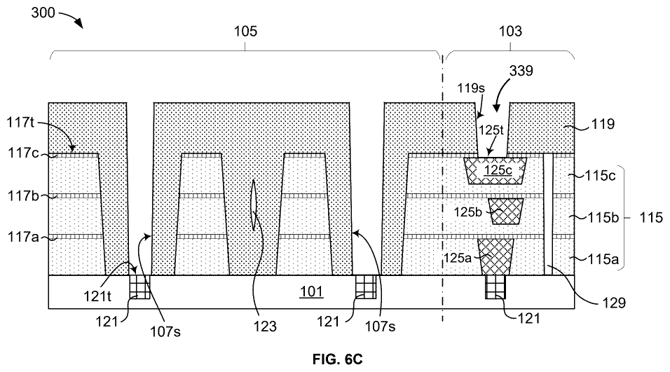

FIGS. 6A-6C illustrate an alternative process flow for fabricating the section of semiconductor chip 300 shown in FIG. 3, according to exemplary embodiments of the invention. FIGS. 6A and 6B are generally similar to FIGS. 4A and 4B with a number of differences. For example, an additional shaft opening 337 is formed in the active region in FIG. 6A, and the oxide layer 119 over the dielectric layer 115 in FIGS. 4A and 4B is absent in FIGS. 6A and 6B. The processes described in FIG. 4A are generally the same for the formation of the interconnect stack 102′ in FIG. 6A, but excludes the oxide layer 119 for FIG. 6A. The processes to form trenches 131, 133 and 135 in the chip edge region in FIG. 6A are similar to the processes for forming trenches 131, 133 and 135 in FIG. 4A and will not be repeated here. The process for forming the shaft opening 337 in the interconnect stack 102′ is similar to the process for forming trenches 131, 133 and 135m, and may be formed in the same process step in some embodiments.

Next referring to FIG. 6B, insulator layer 107 may be formed over the interconnect stack 102′ according to suitable deposition techniques as aforementioned. For example, the insulator layer 107 may be formed over the top surface 117t of the topmost barrier layer 117c. The insulator layer 107 may also be deposited within the trenches 131, 133 and 135, over the exposed side surfaces 115s of the dielectric material layers and over the top surface 101t of the substrate 101. Similar to FIG. 4B, in some of the trenches, the insulator layer 107 may fill up the trench to a level above the top surface 117t of the topmost barrier layer 117c, and include an air gap enclosed within the portion of insulator layer 107 in the trench 133. For example, trench 133 has an air gap 123 enclosed within the portion of insulator layer 107 in the trench 133, above the substrate 101. In other trenches, for example, trenches 131 and 135, the insulator layer 107 may conformally line the side walls of the trenches, leaving a gap between the opposing outer side walls 107s of the insulator layer 107. The insulator layer 107 may also line the bottom surfaces of the trenches 131 and 135, for example, bottom portions of the insulator layer 107 may cover the top surface 121t of some contacts in the chip edge region 105, for example contacts 121A and 121B. Due to the narrow width and high aspect ratio of the shaft opening 337, the insulator layer 107 does not enter the shaft opening to fill it up. Instead, the insulator layer 107 covers over the top of the shaft opening 337 to form an enclosed an air gap 129 within the dielectric layer 115.

Next referring to FIG. 6C, a material removal process may be performed in both the active region 103 and the chip edge region 105. A through-opening 339 may be formed in the oxide layer 119 in the chip edge region, exposing a top surface 125t of the conductive line 125 at the bottom of the opening 339. In some embodiments, the opening 339 may extend through the topmost barrier layer over the dielectric layer 115, for example, barrier layer 117c. The material removal process may simultaneously remove the bottom portions of the insulator layer 107 in trenches 131 and 135, exposing the top surfaces 121t of contacts 121A and 121B in the chip edge region 105. Subsequently, trenches 131 and 135 may be filled with a suitable conductive material to form the seal ring segments 109A and 109B shown in FIG. 3. In some embodiments, the opening 339 may also be filled with the same conductive material in the same process step to form the via 113. Suitable conductive materials may include copper and copper alloys, and may be deposited by electroplating.

Descriptions of embodiments herein are meant to be taken as examples and not meant to be limiting as such. Terms such as “vertical”, “horizontal”, “top”, “bottom”, “over”, “under”, and the like in the description and in the claims, if any, are used for establishing a frame of reference and not necessarily for describing permanent relative positions. The term “horizontal” is defined as a plane parallel to a conventional plane of a semiconductor substrate, rather than its actual three-dimensional orientation in space. The terms “vertical” and “normal” refer to a plane perpendicular to the horizontal. The term “lateral” refers to a direction parallel to the horizontal plane.

Terms such as “connected” or “coupled” indicate that a feature may be directly connected or coupled to or with the other feature, or one or more intervening features may also be present. A feature may be “directly connected” or “directly coupled” to or with another feature if intervening features are absent. A feature may be “indirectly connected” or “indirectly coupled” to or with another feature if at least one intervening feature is present. Terms such as “on” or “contacting” indicate that a feature may be directly on or in direct contact with the other feature, or one or more intervening features may also be present. A feature may be “directly on” or in “direct contact” with another feature if intervening features are absent. A feature may be “indirectly on” or in “indirect contact” with another feature if at least one intervening feature is present.

The terms “first”, “second”, “third” and the like in the description and in the claims, if any, are used for distinguishing between similar elements and not necessarily for describing a particular sequential or chronological order as required. A method described herein is not necessarily limited in practice to the exact order or number of steps as have been listed, and certain steps may possibly be omitted and/or certain other steps not described herein may possibly be performed in actual practice. Terms such as “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

While several exemplary embodiments have been presented in the above detailed description of the device, it should be appreciated that number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

What is claimed is:

1. A semiconductor device comprising:
an interconnect layer over a substrate, the interconnect layer comprises a dielectric layer over the substrate and a barrier layer over the dielectric layer;
a seal ring in the interconnect layer, the seal ring extends through the interconnect layer to abut the substrate;
an insulator layer around the seal ring; and
a protective structure laterally adjacent to the seal ring, the protective structure extends through the interconnect layer to abut the substrate.

2. The semiconductor device of claim 1, wherein the insulator layer has a dielectric constant that is higher than the dielectric constant of the dielectric layer.

3. The semiconductor device of claim 1, further comprising an active region and a chip edge region, wherein the chip edge region surrounds the active region, the seal ring is in the chip edge region and the protective structure is between the seal ring and the active region.

4. The semiconductor device of claim 3, wherein the protective structure is continuous and annularly surrounds the active region.

5. The semiconductor device of claim 1, wherein the seal ring is discontinuous and comprises discrete segments.

6. The semiconductor device of claim 5, wherein the protective structure is between the discrete segments of the seal ring.

7. The semiconductor device of claim 1, further comprising an air gap in the interconnect layer.

8. The semiconductor device of claim 7, wherein the air gap is in a chip edge region.

9. The semiconductor device of claim 7, wherein the air gap is in an active region.

10. The semiconductor device of claim 1, wherein the barrier layer is discontinuous where the seal ring extends through the interconnect layer and the insulator layer spaces the seal ring from the barrier layer.

11. The semiconductor device of claim 1, wherein the insulator layer and the protective structure comprise the same material.

12. The semiconductor device of claim 1, further comprising a contact in the substrate, wherein the seal ring is connected to the contact.

13. The semiconductor device of claim 1, further comprising a via above the dielectric layer, wherein the via comprises the same material as the seal ring.

14. A semiconductor device comprising:
an interconnect stack over a substrate, wherein the interconnect stack comprises a first dielectric layer, a barrier layer over the first dielectric layer and a second dielectric layer over the barrier layer;
a first trench in the interconnect stack, wherein the first trench extends through the barrier layer to abut the substrate and the first trench has a first sidewall;
an insulator layer on the first sidewall of the first trench;
a first seal ring segment in the first trench, wherein the first seal ring segment is spaced from the barrier layer by the insulator layer; and
a protective structure in the interconnect stack, wherein the protective structure is laterally adjacent to the first seal ring segment and extends through the barrier layer to abut the substrate.

15. The semiconductor device of claim 14, further comprising a second trench in the interconnect stack, and a second seal ring segment in the second trench.

16. The semiconductor device of claim 15, wherein the protective structure is between the first seal ring segment and the second seal ring segment.

17. The semiconductor device of claim 15, wherein the second seal ring segment is spaced from the barrier layer by the insulator layer.

18. A method of fabricating a semiconductor device comprising:
forming an interconnect stack over a substrate, wherein the interconnect stack comprises a first dielectric layer, a barrier layer over the first dielectric layer and a second dielectric layer over the barrier layer;
forming a first trench in the interconnect stack, wherein the first trench extends through the barrier layer to abut the substrate and the first trench has a first sidewall;
forming an insulator layer on the first sidewall of the first trench;
forming a first seal ring segment in the first trench, wherein the first seal ring segment is spaced from the barrier layer by the insulator layer; and
forming a protective structure in the interconnect stack, wherein the protective structure is laterally adjacent to the first seal ring segment and extends through the barrier layer to abut the substrate.

19. A method according to claim 18 wherein the insulator layer and the protective structure are formed from the same material.

20. A method according to claim 18 further comprising:
forming a second trench in the interconnect stack, wherein the second trench extends through the barrier layer to abut the substrate;
forming a second insulator layer in the second trench; and
forming a second seal ring segment in the second trench, wherein the second seal ring segment is spaced from the barrier layer by the second insulator layer.
